(19) United States
(12) Patent Application Publication
(10) Pub. No.: US 2025/0194169 A1
(43) Pub. Date: Jun. 12, 2025

(54) TERMINATION STRUCTURE FOR A SEMICONDUCTOR DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US); Bruce Odekirk, Portland, OR (US); Randy L. Yach, Phoenix, AZ (US)

(73) Assignee: Microchip Technology Incorporated, Chandler, AZ (US)

(21) Appl. No.: 18/740,011

(22) Filed: Jun. 11, 2024

Related U.S. Application Data
(60) Provisional application No. 63/608,598, filed on Dec. 11, 2023.

(51) Int. Cl. H01L 29/06; H01L 21/762

(52) U.S. Cl. CPC H10D 62/102; H01L 21/76237

(57) ABSTRACT

A termination structure for a semiconductor device that may include a substrate having a first type dopant. A plurality of doped-wells having a second type dopant formed in the substrate. A plurality of trenches formed into the plurality of doped-wells, respective ones of the formed trenches exposing a bottom surface of the doped-well, and exposing side surfaces of the doped-well, and a material within respective ones of the formed trenches, wherein the material in respective ones of the formed trenches is surrounded by the exposed bottom surface of the doped-well of the respective formed trench and the exposed side surfaces of the doped-well of the respective formed trench.

### CROSS-REFERENCE TO RELATED APPLICATION

The present application claims priority to U.S. Provisional Patent Application No. 63/608,598, filed on Dec. 11, 2023, the contents of which are hereby incorporated by reference in their entirety.

### TECHNICAL FIELD

The present disclosure relates generally to termination structures for semiconductor devices, and more specifically to methods for manufacturing same to decrease the amount of space used on a substrate for a power device.

### SUMMARY

According to an aspect of one or more examples, there is provided a method for fabricating a termination structure for a semiconductor device. The method may include providing a substrate having a first type dopant, forming a plurality of doped-wells having a second type dopant in the substrate, forming a plurality of trenches into the plurality of doped-wells, respective ones of the formed trenches exposing a bottom surface of the doped-wells and exposing side surfaces of the doped-wells, and depositing a material into respective ones of the formed trenches, wherein the deposited material in respective ones of the formed trenches is surrounded by the exposed bottom surface of the doped-wells of the respective formed trench and the exposed side surfaces of the doped-wells of the respective formed trench. The deposited material may include an insulator material. The deposited material may include polysilicon or silicon dioxide or a mixture of polysilicon and silicon dioxide. The method may include forming a doped-layer over the formed plurality of doped-wells in the substrate, the doped-layer having the second dopant type, wherein forming the plurality of trenches into the plurality of doped-wells comprises exposing side surfaces of the doped-layer, exposing the bottom surface of the doped-well and exposing the side surfaces of the doped-well, wherein the deposited material in respective ones of the formed trenches is surrounded by the exposed bottom surface of the doped-well of the respective formed trench, the exposed side surfaces of the doped-well of the respective formed trench and the exposed side surfaces of the doped-layer of the respective formed trench. The deposited material may include an insulator material. The deposited material may include polysilicon or silicon dioxide or a mixture of polysilicon and silicon dioxide.

According to an aspect of one or more examples, there is provided a method for fabricating a termination structure for a semiconductor device. The method may include providing a substrate having a first type dopant, forming a plurality of doped-wells having a second type dopant in the substrate, forming a plurality of trenches into the plurality of doped-wells, respective ones of the formed trenches exposing a bottom surface of the doped-well, exposing side surfaces of the doped-well and exposing side surfaces of the substrate, and depositing a material into respective ones of the formed trenches, wherein the deposited material in respective ones of the formed trenches is surrounded by the exposed bottom surface of the doped-well of the respective formed trench, the exposed side surfaces of the doped-well of the respective formed trench and the exposed side surfaces of the substrate of the respective formed trench. The deposited material may include an insulator material. The deposited material may include polysilicon or silicon dioxide or a mixture of polysilicon and silicon dioxide. The method may include forming a doped-layer over the formed plurality of doped-wells in the substrate, the doped-layer having the second dopant type, wherein forming the plurality of trenches into the plurality of doped-wells, respective ones of the formed trenches exposing side surfaces of the doped-layer, exposing the side surfaces of the substrate, exposing the side surfaces of the doped-well and exposing the bottom surface of the doped-well, wherein the deposited material in respective ones of the formed trenches is surrounded by the exposed bottom surface of the doped-well of the respective formed trench, the exposed side surfaces of the doped-well of the respective formed trench, the exposed side surfaces of the substrate of the respective formed trench and the exposed side surfaces of the doped-layer of the respective formed trench. The deposited material may include an insulator material. The deposited material may include polysilicon or silicon dioxide or a mixture of polysilicon and silicon dioxide.

According to an aspect of various examples, there is provided a termination structure for a semiconductor device. The termination structure may include a substrate having a first type dopant, a plurality of doped-wells having a second type dopant formed in the substrate, a plurality of trenches formed into the plurality of doped-wells, respective ones of the formed trenches exposing a bottom surface of the doped-well, and exposing side surfaces of the doped-well, and a material within respective ones of the formed trenches, wherein the material in respective ones of the formed trenches is surrounded by the exposed bottom surface of the doped-well of the respective formed trench and the exposed side surfaces of the doped-well of the respective formed trench. The termination structure can include a doped-layer over the formed plurality of doped-wells in the substrate, the doped-layer having the second dopant type, respective ones of the formed trenches exposing side surfaces of the doped-layer, exposing the bottom surface of the doped-well and exposing the side surfaces of the doped-well, wherein the material in respective ones of the formed trenches is surrounded by the exposed side surfaces of the doped-layer of the respective formed trench, the exposed bottom surface of the doped-well of the respective formed trench, and the exposed side surfaces of the doped-well of the respective formed trench. The material in the formed trench of the termination structure may include an insulator material. The material in the formed trench of the termination structure may include polysilicon or silicon dioxide or a mixture of polysilicon and silicon dioxide.

According to an aspect of various examples, there is provided a termination structure for a semiconductor device. The termination structure may include a substrate having a first type dopant, a plurality of doped-wells having a second type dopant formed in the substrate, a plurality of trenches formed into respective ones of the plurality of doped-wells, respective ones of the formed trenches exposing a bottom surface of the doped-well, exposing side surfaces of the doped-well and exposing side surfaces of the substrate, and a material within respective ones of the formed trenches, wherein the material in respective ones of the formed trenches is surrounded by the exposed bottom surface of the doped-well of the respective formed trench, the exposed side surfaces of the doped-well of the respective formed trench and the exposed side surfaces of the substrate of the respective formed trench. The termination structure may include a doped-layer over the formed plurality of doped-wells in the substrate, the doped-layer having the second dopant type, respective ones of the formed trenches exposing side surfaces of the doped-layer, exposing side surfaces of the substrate, exposing the bottom surface of the doped-well and exposing the side surfaces of the doped-well, wherein the material in respective ones of the formed trenches is surrounded by the exposed bottom surface of the doped-well of the respective formed trench, the exposed side surfaces of the doped-well of the respective formed trench, the exposed side surfaces of the doped-layer of the respective formed trench and the exposed side surfaces of the substrate of the respective formed trench. The material in the formed trench of the termination structure may include an insulator material. The material in the formed trench of the termination structure may include polysilicon or silicon dioxide or a mixture of polysilicon and silicon dioxide.

### BRIEF DESCRIPTION OF DRAWINGS

FIG. 1 shows a cross-sectional view of a substrate of a semiconductor device having a doped-layer with a termination structure having a plurality of doped-wells having a trench filled with deposited material where the deposited material in the trenches is surrounded by the remaining surfaces of the doped-wells and the remaining surfaces of the doped-layer according to one or more examples;

FIG. 2 shows a cross-sectional view of a substrate of a semiconductor device with a termination structure having a plurality of doped-wells having a trench filled with deposited material where the deposited material in the trenches is surrounded by the remaining surfaces of the doped-wells according to one or more examples;

FIG. 3 shows a cross-sectional view of substrate of a semiconductor device having a doped-layer with a termination structure having a plurality of doped-wells having a trench filled with deposited material where the deposited material in the trenches is surrounded by the remaining surfaces of the doped-wells, the remaining surfaces of the substrate and the remaining surfaces of the doped-layer according to one or more examples; and

FIG. 4 shows a cross-sectional view of a substrate of a semiconductor device with a termination structure having a plurality of doped-wells having a trench filled with deposited material where the deposited material in the trenches is surrounded by the remaining surfaces of the doped-wells and the remaining surfaces of the substrate according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Power semiconductor devices rely on one or more p-n junctions between a p-type semiconductor and an n-type semiconductor. An active region of the junction emits an electric field in a lateral direction, which can negatively affect performance of the device. To reduce the electric field emitted in the lateral direction, guard rings or terminations may be formed in the substrate of the semiconductor device. For example, a semiconductor device with a first dopant type, e.g., an n-type substrate, may have a doped-well with a second dopant type, e.g., p-well, that forms an active region p-n junction with the n-type substrate. A plurality of p-type terminations may be formed laterally adjacent to the active region to reduce the electric field that is emitted laterally. A field oxide layer may be formed on the substrate, and may extend laterally beyond the last termination of the plurality of terminations. However, for higher voltage devices there is a need to increase the number of terminations rings, with a concomitant increase in area for each power semiconductor device, to withstand the higher voltages of the power device. As a result, there is a loss of revenue since there are less dies per wafer to accommodate the increased area used by the power semiconductor devices. Accordingly, there is a need for an edge termination structure that uses less area. Various examples are provided below based on a first dopant type (n-type substrate) with doped-wells with a second dopant type (p-wells), it being understood that a p-type substrate with n-wells may be utilized with the same termination structure. Thus, in one example, an n-type may be considered a first type, and a p-type may be considered a second type. In another example, a p-type may be considered a first type, and a n-type may be considered a second type.

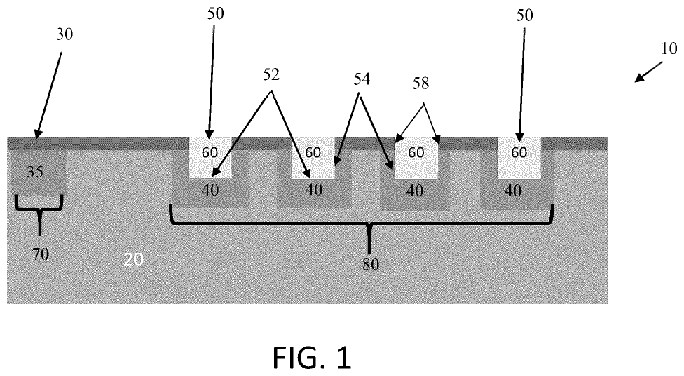

FIG. 1 shows a cross-sectional view of a substrate 20 having a first dopant type of a semiconductor device 10 having a doped-layer 30 having a second dopant type implanted into the substrate 20 at a top surface thereof, having an active device region 70 and a termination structure 80. The termination structure 80 comprises a plurality of doped-wells 40 having the second dopant type formed in substrate 20, respective ones of the plurality of doped-wells 40 having a trench 50 filled with deposited material 60 according to one or more examples. The active device region 70, of which only a portion is shown, may comprise a doped-well 35 having the second dopant type, and the termination structure 80 may extend laterally past the end of active device region 70. As shown in FIG. 1, the termination structure 80 for the semiconductor device 10 may include the substrate 20, which may be made of a first type doped semiconductor such as silicon or silicon carbide. Doped-well 35 having a second type dopant may be implanted in the first type doped substrate 20 to create a p-n junction that forms an active region 70 with a second type doped-layer 30, and second type doped-wells 40 may be implanted in the n-type substrate 20 to form the termination structure 80 for the semiconductor device 10. The second type doped-layer 30, with a concentration of the second type dopant which may be greater than the concentration of the second type dopant in the plurality of second type doped-wells 35, 40, may be implanted over the implanted plurality of second type doped-wells 35, 40 into the upper surface of the substrate 20. A trench 50 can be formed, e.g., by etching, into the second type doped layer 30 and into one or more of the implanted plurality of second type doped wells 40 exposing a bottom surface 52 of the respective second type doped wells 40, exposing walls 54 of the respective second type doped wells 40, and exposing walls 58 of the respective portion of the second type doped-layer 30. An insulating material 60 such as, but not limited to, polysilicon or silicon dioxide or a mixture of polysilicon and silicon dioxide can be deposited into the respective trenches 50 that were formed in the respective second type doped wells 40. As shown in FIG. 1, the deposited material 60 can be surrounded within the respective trench 50 by the exposed bottom surface 52 of the respective second type doped well 40, the exposed walls 54 of the respective second type doped well 40, and the exposed walls 58 of the respective portion of the second type doped layer 30. As shown in FIG. 1, the deposited material 60 within the respective trenches which can be surrounded by the exposed bottom surface 52 of the respective second type doped well 40, the exposed walls 54 of the respective second type doped well 40, and the exposed walls 58 of the respective portion of the second type doped layer 30 form the termination structure 80. The term “surrounded” as used herein refers to the bottom and sides of the deposited material 60, without reference to a top of the deposited material 60. The termination structure 80 improves the breakdown voltage characteristics by shifting the maximum electric field from the surface of the substrate 20 and reducing the peak value. In addition, as a non-limiting example where the second type is a p-type, in the case of an n-type substrate 20 a p-type impurity, such as aluminum, can be implanted into the exposed bottom surface 52 of the trench etched second type doped-well 40 to make the respective second type doped-well 40 physically deeper as the p-type impurity is implanted after trench 50 formation. Alternatively, in the case of a p-type substrate a n-type impurity, such as nitrogen, can be implanted into the exposed bottom surface 52 of the trench etched second type doped-well 40 to make the respective second type doped-well 40 physically deeper as the n-type impurity is implanted after trench 50 formation. The effects of this termination structure 80 increase the cylindrical junction curvature and enable a deeper and wider potential profile. As indicated above, FIG. 1 is a cross-sectional view of termination structure 80, which termination structure 80 is generally understood to be formed as guard rings around active device region 70.

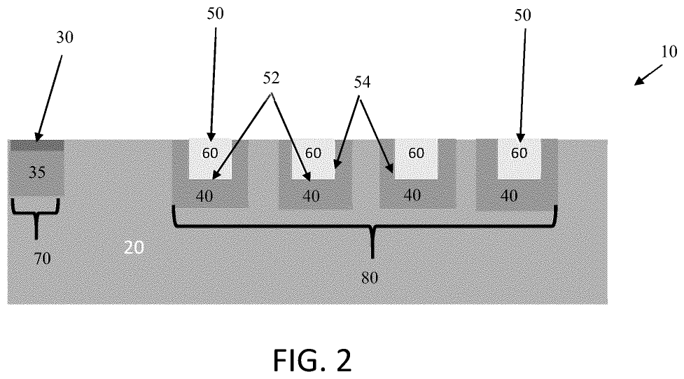

FIG. 2 shows a cross-sectional view of a substrate 20 having a first dopant type for semiconductor device 10 having an active device region 70 and a termination structure 80. The termination structure 80 comprises a plurality of doped-wells 40 having a second dopant type formed in substrate 20, respective ones of the plurality of doped-wells 40 having a trench 50 filled with deposited material 60 according to one or more examples. As shown in FIG. 2, the termination structure for the semiconductor device 10 may include a substrate 20, which may be made of a first type doped semiconductor such as silicon or silicon carbide. Active device region 70, of which only a portion is shown, may comprise a second type doped-well 35, and a second type doped-layer 30 implanted into the substrate 20 at a top surface thereof. A concentration of the second type dopant in the second type doped layer 30 may be greater than the concentration of the second type dopant in the plurality of second type doped-wells 35, 40. Termination structure 80 may extend laterally past the end of active device region 70. A plurality of second type doped-wells 40 may be implanted in the first type doped substrate 20 to create the termination structure 80 for the semiconductor device 10. A trench 50 can be formed, e.g., by etching, into one or more of the implanted plurality of second type doped-wells 40 exposing a bottom surface 52 of the respective second type doped-wells 40 and exposing walls 54 of the respective second type doped-wells 40. An insulating material 60 such as, but not limited to, polysilicon or silicon dioxide or a mixture of polysilicon and silicon dioxide can be deposited into the trench 50 that was formed in the respective second type doped-wells 40. As shown in FIG. 2, the deposited material 60 can be surrounded within the respective trench 50 by the exposed bottom surface 52 of the respective second type doped-well 40 and the exposed walls 54 of the respective second doped-well 40 form the termination structure 80. The termination structure 80 improves the breakdown voltage characteristics by shifting the maximum electric field from the surface of the substrate 20 and reducing the peak value. In addition, in the case of an n-type substrate 20, i.e. wherein the first type is an n-type, a p-type impurity, such as aluminum, can be implanted into the exposed bottom surface 52 of the trench etched second type doped-well 40 to make the respective second type doped-well 40 physically deeper as the p-type impurity is implanted after trench 50 formation. Alternatively, in the case of a p-type substrate 20, i.e. where the first type is a p-type, a n-type impurity, such as nitrogen, can be implanted into the exposed bottom surface 52 of the trench etched second type doped-well 40 to make the respective second type doped-well 40 physically deeper as the n-type impurity is implanted after trench 50 formation. The effects of this termination structure 80 increase the cylindrical junction curvature and enable a deeper and wider potential profile. As indicated above, FIG. 2 is a cross-sectional view of termination structure 80, which termination structure 80 is generally understood to be formed as guard rings around active device region 70.

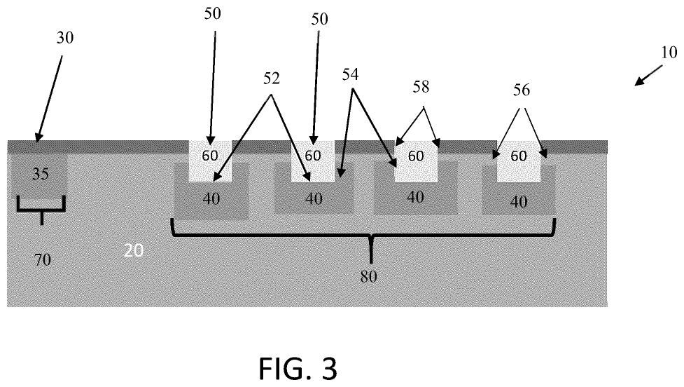

FIG. 3 shows a cross-sectional view of a substrate 20 having a first dopant type having a doped-layer 30 having a second dopant type implanted into the substrate 20 at a top surface thereof, having an active device region 70 and a termination structure 80. The termination structure 80 comprises a plurality of doped-wells 40 having the second dopant type formed in substrate 20, respective ones of the plurality of second type doped-wells 40 having a trench 50 filled with deposited material 60 according to one or more examples. As shown in FIG. 3, the termination structure 80 for the semiconductor device 10 may include the substrate 20, which may be made of an first type doped semiconductor such as silicon or silicon carbide. Active device region 70, of which only a portion is shown, may comprise a second type doped-well 35, and a second type doped-layer 30 implanted into the substrate 20 at a top surface thereof. Termination structure 80 may extend laterally past the end of active device region 70. A plurality of buried second type doped-wells 40 may be implanted in the n-type substrate 20 to form the termination structure 80 of the semiconductor device 10. The second type doped-layer 30 may be implanted over the implanted second type doped-well 35 and over the implanted plurality of second type doped-wells 40 into the upper surface of the substrate 20. A concentration of the second type dopant in the second type doped layer 30 may be greater than the concentration of the second type dopant in the plurality of second type doped-wells 35, 40. A trench 50 can be formed, e.g., by etching, into the second type doped-layer 30 and into the one or more of the plurality of second type doped wells 40 exposing walls 58 of the respective portion of the second type doped-layer 30, exposing walls 56 of the respective portion of the first type doped substrate 20, exposing a bottom surface 52 of the respective second type doped-well 40, and exposing walls 54 of the respective second type doped-wells 40. An insulating material 60 such as, but not limited to, polysilicon or silicon dioxide or a mixture of polysilicon and silicon dioxide can be deposited into respective ones of the trenches 50 that was formed in the second type doped-wells 40. As shown in FIG. 3, the deposited material 60 in a respective trench 50 can be surrounded within the respective trench 50 by the exposed walls 56 of the respective portion of the first type doped substrate 20, the exposed bottom surface 52 of the respective second type doped-well 40, the exposed walls 54 of the respective second type doped-well 40, and the exposed walls 58 of the respective portion of the second type doped-layer 30. Thus, the deposited material 60 is only partially surrounded by the exposed bottom surface 52 of the respective second type doped-well 40, the exposed walls 54 of the respective second type doped-well 40, and the exposed walls 58 of the respective portion of the second type doped-layer. The termination structure 80 improves the breakdown voltage characteristics by shifting the maximum electric field from the surface of the substrate 20 and reducing the peak value. In addition, in the case of an n-type substrate 20, i.e. wherein the first type is an n-type, a p-type impurity, such as aluminum, can be implanted into the exposed bottom surface 52 of the trench etched second type doped-well 40 to make the respective second type doped-well 40 physically deeper as the p-type impurity is implanted after trench 50 formation. Alternatively, in the case of a p-type substrate, i.e. where the first type is a p-type, a n-type impurity, such as nitrogen, can be implanted into the exposed bottom surface 52 of the trench etched doped-well 40 to make the respective doped-well 40 physically deeper as the n-type impurity is implanted after trench 50 formation. The effects of this termination structure 80 increase the cylindrical junction curvature and enable a deeper and wider potential profile. As indicated above, FIG. 3 is a cross-sectional view of termination structure 80, which termination structure 80 is generally understood to be formed as guard rings around active device region 70.

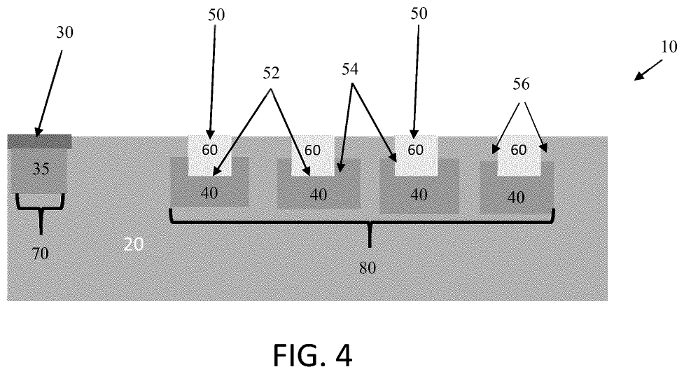

FIG. 4 shows a cross-sectional view of a substrate 20 having a first dopant type having an active device region 70 and a termination structure 80. The termination structure 80 comprises a plurality of buried doped-wells 40 having a second dopant type formed in substrate 20, respective ones of the plurality of buried second type doped-wells 40 having a trench 50 filled with deposited material 60 according to one or more examples. As shown in FIG. 4, the termination structure 80 for the semiconductor device 10 may include the substrate 20, which may be made of an first type doped semiconductor such as silicon or silicon carbide. Active device region 70, of which only a portion is shown, may comprise a second type doped-well 35, and termination structure 80 may extend laterally past the end of active device region 70. Termination structure 80 may comprise a plurality of buried second type doped-wells 40 implanted in the first type substrate 20. A second type doped-layer 30 may be implanted over the second type doped-well 35 in the active area 70. A concentration of the second type dopant in the second type doped layer 30 may be greater than the concentration of the second type dopant in the plurality of second type doped-wells 35, 40. A trench 50 can be formed, e.g., by etching, into one or more of the implanted plurality of buried second type doped-wells 40 exposing a bottom surface 52 of the respective second type doped-well 40, exposing walls 54 of the respective second type doped-well 40, and exposing walls 56 of the respective portion of the first type doped substrate 20. An insulating material 60 such as, but not limited to, polysilicon or silicon dioxide or a mixture of polysilicon and silicon dioxide can be deposited into the respective trenches 50 that was formed in the doped-wells 40. As shown in FIG. 4, the deposited material 60 can be surrounded within the respective trench 50 by the exposed walls 56 of the respective portion of the first type doped substrate 20, the exposed bottom surface 52 of the respective second type doped-well 40, and the exposed walls 54 of the respective second type doped-well 40. Thus, the deposited material 60 is only partially surrounded by the exposed bottom surface 52 of the respective second type doped-well 40 and the exposed walls 54 of the respective second type doped-well 40. The termination structure 80 improves the breakdown voltage characteristics by shifting the maximum electric field from the surface of the substrate 20 and reducing the peak value. In addition, in the case of an n-type substrate 20, i.e. where the first type is an n-type, a p-type impurity, such as aluminum, can be implanted into the exposed bottom surface 52 of the trench etched doped-well 40 to make the respective doped-well 40 physically deeper as the p-type impurity is implanted after trench 50 formation. Alternatively, in the case of a p-type substrate 20, i.e. where the first type is a p-type, a n-type impurity, such as nitrogen, can be implanted into the exposed bottom surface 52 of the trench etched doped-well 40 to make the respective doped-well 40 physically deeper as the n-type impurity is implanted after trench 50 formation. The effects of this termination structure 80 increase the cylindrical junction curvature and enable a deeper and wider potential profile. As indicated above, FIG. 4 is a cross-sectional view of termination structure 80, which termination structure 80 is generally understood to be formed as guard rings around active device region 70.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method for fabricating a termination structure for a semiconductor device, the method comprising:
providing a substrate having a first type dopant;
forming a plurality of doped-wells having a second type dopant in the substrate;
forming a plurality of trenches into the plurality of doped-wells, respective ones of the formed trenches exposing a bottom surface of the doped-wells and exposing side surfaces of the doped-wells; and
depositing a material into respective ones of the formed trenches, wherein the deposited material in respective ones of the formed trenches is surrounded by the exposed bottom surface of the doped-wells of the respective formed trench and the exposed side surfaces of the doped-wells of the respective formed trench.

2. The method of claim 1, wherein the deposited material comprises an insulator material.

3. The method of claim 1, wherein the deposited material comprises polysilicon, silicon dioxide, or a mixture of polysilicon and silicon dioxide.

4. The method of claim 1, comprising forming a doped-layer over the formed plurality of doped-wells in the substrate, the doped-layer having the second dopant type; wherein forming the plurality of trenches into the plurality of doped-wells comprises exposing side surfaces of the doped-layer, exposing the bottom surface of the doped-well and exposing the side surfaces of the doped-well; wherein the deposited material in respective ones of the formed trenches is surrounded by the exposed bottom surface of the doped-well of the respective formed trench, the exposed side surfaces of the doped-well of the respective formed trench and the exposed side surfaces of the doped-layer of the respective formed trench.

5. The method of claim 4, wherein the deposited material comprises an insulator material.

6. The method of claim 4, wherein the deposited material comprises polysilicon, silicon dioxide, or a mixture of polysilicon and silicon dioxide.

7. A method for fabricating a termination structure for a semiconductor device, the method comprising:
providing a substrate having a first type dopant;
forming a plurality of doped-wells having a second type dopant in the substrate;
forming a plurality of trenches into the plurality of doped-wells, respective ones of the formed trenches exposing a bottom surface of the doped-well, exposing side surfaces of the doped-well and exposing side surfaces of the substrate; and
depositing a material into respective ones of the formed trenches, wherein the deposited material in respective ones of the formed trenches is surrounded by the exposed bottom surface of the doped-well of the respective formed trench, the exposed side surfaces of the doped-well of the respective formed trench and the exposed side surfaces of the substrate of the respective formed trench.

8. The method of claim 7, wherein the deposited material comprises an insulator material.

9. The method of claim 7, wherein the deposited material comprises polysilicon, silicon dioxide, or a mixture of polysilicon and silicon dioxide.

10. The method of claim 7, comprising forming a doped-layer over the formed plurality of doped-wells in the substrate, the doped-layer having the second dopant type; wherein forming the plurality of trenches into the plurality of doped-wells, respective ones of the formed trenches exposing side surfaces of the doped-layer, exposing the side surfaces of the substrate, exposing the side surfaces of the doped-well and exposing the bottom surface of the doped-well; wherein the deposited material in respective ones of the formed trenches is surrounded by the exposed bottom surface of the doped-well of the respective formed trench, the exposed side surfaces of the doped-well of the respective formed trench, the exposed side surfaces of the substrate of the respective formed trench and the exposed side surfaces of the doped-layer of the respective formed trench.

11. The method of claim 10, wherein the deposited material comprises an insulator material.

12. The method of claim 10, wherein the deposited material comprises polysilicon, silicon dioxide, or a mixture of polysilicon and silicon dioxide.

13. A termination structure for a semiconductor device comprising:
a substrate having a first type dopant;
a plurality of doped-wells having a second type dopant formed in the substrate;
a plurality of trenches formed into the plurality of doped-wells, respective ones of the formed trenches exposing a bottom surface of the doped-well, and exposing side surfaces of the doped-well; and
a material within respective ones of the formed trenches, wherein the material in respective ones of the formed trenches is surrounded by the exposed bottom surface of the doped-well of the respective formed trench and the exposed side surfaces of the doped-well of the respective formed trench.

14. The termination structure of claim 13, comprising a doped-layer over the formed plurality of doped-wells in the substrate, the doped-layer having the second dopant type; respective ones of the formed trenches exposing side surfaces of the doped-layer, exposing the bottom surface of the doped-well and exposing the side surfaces of the doped-well; wherein the material in respective ones of the formed trenches is surrounded by the exposed side surfaces of the doped-layer of the respective formed trench, the exposed bottom surface of the doped-well of the respective formed trench, and the exposed side surfaces of the doped-well of the respective formed trench.

15. The termination structure of claim 14, wherein the material comprises an insulator material.

16. The termination structure of claim 14, wherein the material comprises polysilicon, silicon dioxide, or a mixture of polysilicon and silicon dioxide.

17. A termination structure for a semiconductor device comprising:
a substrate having a first type dopant;
a plurality of doped-wells having a second type dopant formed in the substrate;
a plurality of trenches formed into respective ones of the plurality of doped-wells, respective ones of the formed trenches exposing a bottom surface of the doped-well, exposing side surfaces of the doped-well and exposing side surfaces of the substrate; and
a material within respective ones of the formed trenches, wherein the material in respective ones of the formed trenches is surrounded by the exposed bottom surface of the doped-well of the respective formed trench, the exposed side surfaces of the doped-well of the respective formed trench and the exposed side surfaces of the substrate of the respective formed trench.

18. The termination structure of claim 17, comprising a doped-layer over the formed plurality of doped-wells in the substrate, the doped-layer having the second dopant type; respective ones of the formed trenches exposing side surfaces of the doped-layer, exposing side surfaces of the substrate, exposing the bottom surface of the doped-well and exposing the side surfaces of the doped-well; wherein the material in respective ones of the formed trenches is surrounded by the exposed bottom surface of the doped-well of the respective formed trench, the exposed side surfaces of the doped-well of the respective formed trench, the exposed side surfaces of the doped-layer of the respective formed trench and the exposed side surfaces of the substrate of the respective formed trench.

19. The termination structure of claim 18, wherein the material comprises an insulator material.

20. The termination structure of claim 18, wherein the material comprises polysilicon, silicon dioxide, or a mixture of polysilicon and silicon dioxide.
